(19) United States
(12) Patent Application Publication
(10) Pub. No.: US 2011/0308571 A1
(43) Pub. Date: Dec. 22, 2011

(54) Light assembly having parabolic sheets

(76) Inventors: Stephan R. Clark, Albany, OR (US); Karl S. Weibezahn, Corvallis, OR (US); John P. Whitlock, Lebanon, OR (US); Scott Lerner, Corvallis, OR (US)

(21) Appl. No.: 12/819,222

(22) Filed: Jun. 20, 2010

(51) Int. Cl. H01L 31/052; H01L 31/18

(52) U.S. Cl. 136/246; 29/890.033

(57) ABSTRACT

A light assembly includes a first sheet and a second sheet below the first sheet. The first and the second sheets are parabolic in shape. The first sheet has a dichroic surface. The second sheet has a reflective surface.

### GOVERNMENTAL RIGHTS IN THE INVENTION

The invention that is the subject of this patent application was made with Government support under Subcontract No. CW135971, under Prime Contract No. HR0011-07-9-0005, through the Defense Advanced Research Projects Agency (DARPA). The Government has certain rights in this invention.

### BACKGROUND

Traditional approaches to generate electricity have focused on using fossil fuels, such as coal, oil, and natural gas. More recently, for environmental and other reasons, attention has focused on renewable energy sources. Such renewable energy sources include wind, geothermal, and solar. With respect to solar energy in particular, a solar cell is used to convert energy from the sun into electrical energy.

### BRIEF DESCRIPTION OF THE DRAWINGS

FIG. 1 is a diagram of a light assembly including a frame and two sheets, according to an embodiment of the disclosure.

FIG. 2 is a diagram of the light assembly of FIG. 1 where the frame is not shown for illustrative clarity, according to an embodiment of the disclosure.

FIG. 3 is a diagram of a light assembly that also includes two photovoltaic (PV) mechanisms such that the light assembly is a solar cell, according to an embodiment of the disclosure.

FIG. 4 is a flowchart of a method of the operation of the light assembly of FIG. 3, according to an embodiment of the disclosure.

FIG. 5 is a flowchart of a method for manufacturing the light assembly of FIGS. 1 and 2, according to an embodiment of the disclosure.

### DETAILED DESCRIPTION

As noted in the background section, a solar cell is used to convert energy from the sun into electrical energy. While solar energy is gaining traction as an energy source from which to generate electricity, it has so far failed to achieve widespread adoption on the same order that fossil fuel energy sources have. One reason why this is the case is because generating electrical energy from solar energy remains expensive, in part because of the inefficiencies and the manufacturing cost of solar cells.

Embodiments of the disclosure provide for a solar cell that is more efficient than some types of conventional solar cells and that is less expensive to manufacture than other types of conventional solar cells of similar efficiency. A solar cell of an embodiment of the disclosure includes a metal frame to which at least two plastic sheets that are parabolic in shape are mounted. A first plastic sheet is dichroic, and reflects light within a first wavelength range towards a first photovoltaic (PV) mechanism, and transmits light outside this wavelength range towards a second plastic sheet. The second plastic sheet is reflective, and reflects light towards a second PV mechanism.

The parabolic shape of the plastic sheets concentrates the amount of solar energy that is directed towards the PV mechanisms. Efficiency of the solar cell is also increased by the use of a metal frame, which ensures an efficient thermal path of the solar energy. The coefficient of thermal expansion (CTE) of the plastic sheets closely matches the CTE of the metal frame, so that the solar cell has maximum efficiency even when the solar cell experiences a change in temperature. Furthermore, the PV mechanisms are tuned to different solar energy bands to maximize the amount of electrical energy generated by the solar cell as a whole.

The plastic sheets can be manipulated to achieve their parabolic shape. In one type of manipulation process, the plastic sheets are bent and held to the desired shape, whereas in another type of manipulation process, the plastic sheet undergoes thermal forming to realize the desired shape. These types of processes have been found to increase cost linearly with the size of the sheets. In contrast, using injection molding to form the parabolic shape has been found to increase the cost cubically with the size of the sheet. Utilizing plastic in lieu of glass or another material for the sheets also decreases the manufacturing cost of the solar cell.

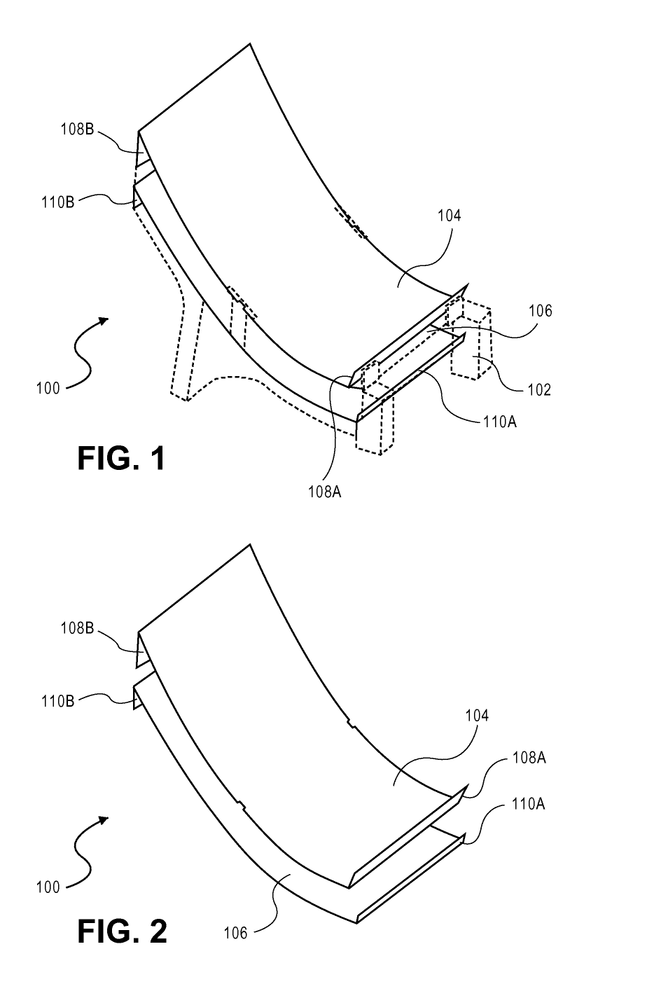

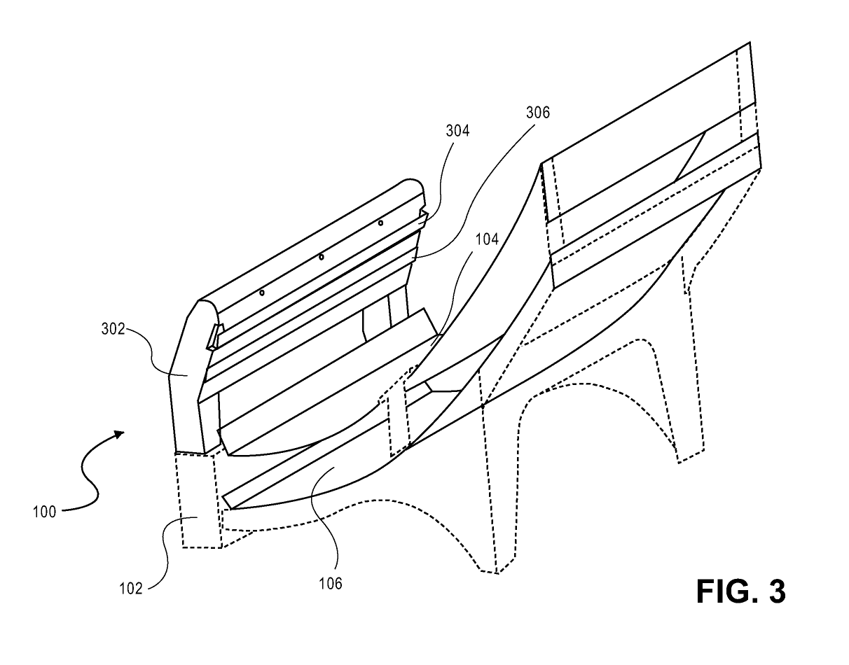

FIGS. 1 and 2 show a light assembly 100, according to an embodiment of the disclosure. The difference between FIGS. 1 and 2 is that a frame 102 of the light assembly 100 is depicted in FIG. 1, but the frame 102 is not depicted in

FIG. 2 so that both plastic sheets 104 and 106 of the assembly 100 are more easily seen. That is, while the light assembly 100 of both FIGS. 1 and 2 includes the frame 102, the frame 102 has been omitted in FIG. 2 for illustrative clarity. To further add illustrative clarity, the edges of the frame 102 are depicted in FIG. 1 using dotted lines.

The light assembly 100 thus includes the frame 102 and the plastic sheets 104 and 106. The frame 102 is metal, such as magnesium. The sheets 104 and 106 are plastic, such as polyethylene naphthalate (PEN), and may have a thickness of 125 micron. The plastic sheets 104 and 106 are mounted to the frame 102. The plastic sheet 106 is mounted to the frame 102 below the plastic sheet 104. The CTE of the plastic sheets 104 and 106 closely matches the CTE of the frame 102. This means that the CTE of the plastic sheets 104 and 106 is similar or identical to the CTE of the frame 102. In one embodiment, the CTE of the plastic sheets 104 and 106 is within plus-or-minus 25% percent (or another threshold) of the CTE of the frame 102, which is about five parts-per-million (ppm) per ° C.

The sheets 104 and 106 are described herein as being plastic sheets. However, more generally, the sheets 104 and 106 may be a material other than plastic. Examples of such other materials include metal, such as polished metal foil, as well as combinations of metal and plastic, such as metalized plastic.

The surface of the plastic sheet 104 is dichroic, which means that the plastic sheet 104 both reflects and transmits light. By comparison, the surface of the plastic sheet 106 is reflective, such that the plastic sheet 106 just reflects light. The plastic sheet 104 is adapted to reflect light having a wavelength range, such as the blue to shorter red wavelengths in the visible light spectrum, and to transmit light outside the wavelength range. As such, the plastic sheet 104 is a high-reflectance and low-wavelength band filter, whereas the plastic sheet 106 is a high-reflectance reflector.

The plastic sheets 104 and 106 have a parabolic shape. The frame 102 thus has a parabolic shape as well where the plastic sheets 104 and 106 are adjacent to the frame 102, in correspondence with the parabolic shape of the sheets 104 and 106. The parabolic shape of the plastic sheets 104 and 106 serves to focus and thus concentrate the light reflected by the sheets 104 and 106. For example, the plastic sheet 104 may focus its reflected light along a first line, and the plastic sheet 106 may focus its reflected light along a second line below the first line.

The plastic sheet 104 has tabs 108A and 108B, collectively referred to as the tabs 108, at its ends, and the plastic sheet 106 likewise has tabs 110A and 110B, collectively referred to as the tabs 110, at its ends. The tabs 108 and 110 increase the stiffness of the plastic sheets 104 and 106, respectively, which permits the shape of the sheets 104 and 106 to be maintained when the sheets 104 and 106 are supported by the frame 102 just at the edges of the sheets 104 and 106. The plastic sheets 104 and 106 are thus mounted to the frame 102 at the tabs 108 and 110, and/or by a suitable adhesive along the edges of contact of the sheets 104 and 106 with the frame 102.

FIG. 3 shows the light assembly 100, according to another embodiment of the disclosure, in which the light assembly 100 is a solar cell. The light assembly 100 of FIG. 3 still includes the frame 102 and the plastic sheets 104 and 106. As in FIG. 1, the frame 102 is depicted using dotted lines in FIG. 3. The light assembly 100 of FIG. 3 also includes a structure 302 and two PV mechanisms 304 and 306. The structure 302 is attached to a lower end of the frame 102. The PV mechanisms 304 and 306 are attached to the structure 302 such that the PV mechanism 306 is below the PV mechanism 304. The PV mechanism 304 and the structure 302 are positioned in relation to one another and in relation to the frame 102 so that the light reflected by the plastic sheet 104 is concentrated along the length of the PV mechanism 304. Likewise, the PV mechanism 306 and the structure 306 are positioned in relation to one another and in relation to the frame 102 so that light reflected by the plastic sheet 106 is concentrated along the length of the PV mechanism 306.

The PV mechanism 304 receives light reflected by the plastic sheet 104 to convert this light into electrical energy, and the PV mechanism 306 receives light reflected by the plastic sheet 106 to convert this light into electrical energy. As noted above, the plastic sheet 104 may reflect the shorter, blue to red wavelengths of light in the visible light spectrum. As such, the PV mechanism 304 is optimized to absorb this light.

By comparison, the plastic sheet 106 reflects the other, longer wavelengths of light outside the visible light spectrum, by virtue of these other wavelengths being transmitted through the plastic sheet 104 to the plastic sheet 106. As such, the PV mechanism 306 is optimized to absorb this light. Therefore, in the parlance of solar cells, the PV mechanism 304 is said to be a mid-E PV cell having a middle energy gap, and the PV mechanism 306 is said to be a low-E PV cell having a low energy gap.

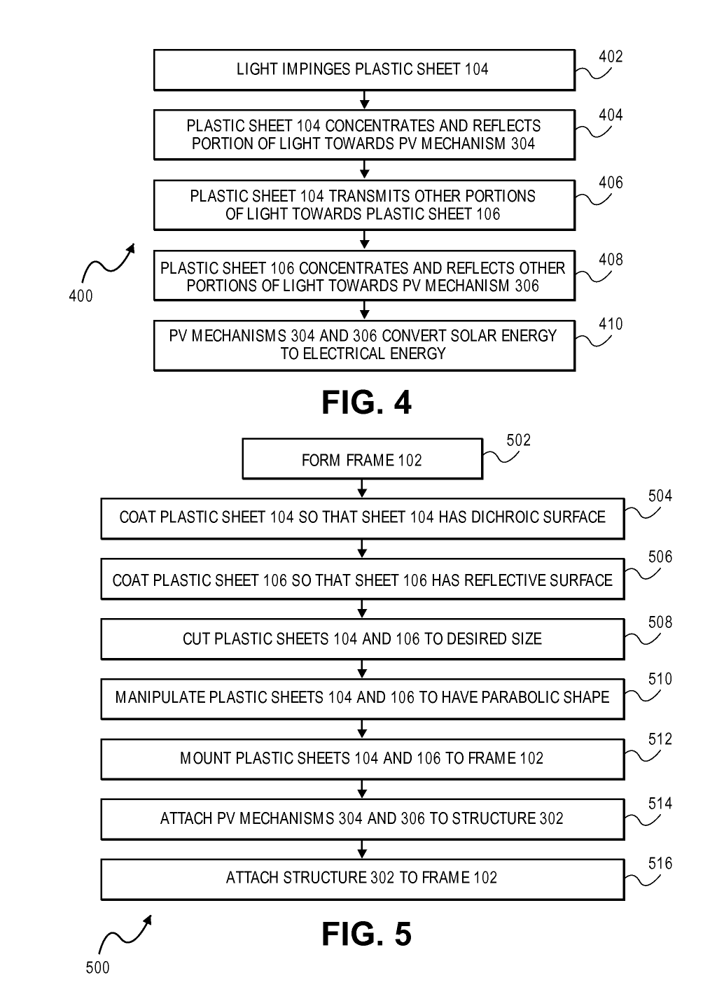

FIG. 4 shows a method 400 of the operation of the light assembly 100 of FIG. 3, according to an embodiment of the disclosure. Light, such as sun light, enters the top of the light assembly 100 and impinges the plastic sheet 104 (402). The plastic sheet 104 concentrates and reflects a portion of the light towards the PV mechanism 304 (404). The plastic sheet 104 transmits other portions of the light towards the plastic sheet 106 (406), which subsequently impinge the sheet 106. The plastic sheet 106 concentrates and reflects these other portions of the light towards the PV mechanism 306 (408). The PV mechanisms 304 and 306 convert the solar energy present to electrical energy (410).

FIG. 5 shows a method 500 for manufacturing the light assembly 100 of FIGS. 1 and 3, according to an embodiment of the disclosure. The frame 102 is formed (502). The frame 102 may be formed by injection molding, cast molding, another type of molding, or another type of technique.

The plastic sheet 104, in a flattened state, is coated so that the sheet 104 has a dichroic surface (504). For example, the plastic sheet 104 may be coated with a series of dielectric layers so that the sheet 104 has a dichroic surface. The opposite surface of the sheet 104 may be coated to minimize reflections of longer wavelengths that are not optimally collected by PV mechanism 304, permitting them to pass to the sheet 106 for redirection to the PV mechanism 306 for optimal collection by the PV mechanism 306. The plastic sheet 106, also in a flattened state, is coated so that the sheet 106 has a reflective surface (506). The plastic sheet 106 may also be coated with a series of dielectric layers, or metal layers and dielectric layers, so that the sheet 106 has a reflective surface. Coating the plastic sheets 104 and 106 in their flattened state provides for greater accuracy in the coating process, as compared to coating the plastic sheets 104 and 106 after they have been placed in their parabolic state.

The plastic sheets 104 and 106, while still flattened, are cut to desired sizes. The plastic sheets 104 and 106 are then manipulated, such as by bending and holding and/or by thermal forming as described above, so that the sheets 104 and 106 have a parabolic shape and the tabs 108 and 110 (510). As such, the plastic sheets 104 and 106 are generally rigid and not flexible. Once the plastic sheets 104 and 106 have been manipulated into their parabolic shape, the sheets 104 and 106 remain in this shape.

With respect to thermal forming in particular, thermal forming the plastic sheets 104 and 106 so that the sheets 104 and 106 have a parabolic shape can be achieved by raising the temperature of the sheets 104 and 106 above their glass transition temperatures while holding the sheets 104 and 106 in a tool of the desired parabolic shape. The plastic sheets 104 and 106 are then permitted to cool below their glass transition temperatures while in the desired parabolic shape. This process imparts the desired unstressed parabolic form on the plastic sheets 104 and 106 so that the sheets 104 and 106 will hold their parabolic shape after removal from the tool. During such thermal forming, the plastic sheets 104 and 106 are not stretched, so that the coatings on the sheets 104 and 106 still maintain their optical performance characteristics relative to their flat coated shape. The plastic sheets 104 and 106 can be mounted to the frame 102 at their tabs 108 and 110 (512), such as by employing screws. The plastic sheets 104 and 106 may further be secured to the frame 102 via a suitable adhesive being applied to the edges of the frame 102 at which the sheets 104 and 106 make contact. Part 512 concludes the method 500 as to manufacture of the light assembly 100 of FIG. 1.

Where the light assembly 100 of FIG. 3 is to be manufactured, the method 500 continues by attachment of the PV mechanisms 304 and 306 to the structure 302 (514), such as by using a thermal adhesive. The structure 302 can include appropriate conductive paths so that the electrical energy generated by the PV mechanisms 304 and 306 can be transferred from the light assembly 100. Finally, the structure 302 is attached to the frame 102 (516), completing the light assembly 100 of FIG. 3.

It is noted that embodiments of the disclosure have been substantially described in relation to a solar cell that converts solar energy to electrical energy. However, the light assembly that has been described can be used for purposes other than functioning as a solar cell. In general, the light assembly includes a frame and at least two plastic sheets as has been described. Light can enter the assembly so that it first impinges the first plastic sheet and then is transmitted through to the second plastic sheet, or so that it first impinges the second plastic sheet and then is reflected to the first plastic sheet.

We claim:

1. A light assembly comprising:
a first sheet being parabolic in shape and having a dichroic surface; and,
a second sheet below the first sheet, the second sheet being parabolic in shape and having a reflective surface.

2. The light assembly of claim 1, wherein each sheet of the first and the second sheets comprises:
a first tab at a first end of the sheet to increase stiffness of the sheet; and,
a second tab at a second end of the sheet to increase stiffness of the sheet.

3. The light assembly of claim 1, wherein the first sheet is adapted to reflect light having a wavelength range and to transmit light outside the wavelength range.

4. The light assembly of claim 1, further comprising a frame to which the first and the second sheets are mounted.

5. The light assembly of claim 4, wherein the frame has a parabolic shape in correspondence with parabolic shapes of the first and the second sheets.

6. The light assembly of claim 4, wherein the frame is metal, and each of the first and the second sheets is plastic.

7. The light assembly of claim 4, wherein the first and the second sheets have a coefficient of thermal expansion (CTE) closely matching a CTE of the frame.

8. The light assembly of claim 1, further comprising:
a first photovoltaic (PV) mechanism to receive light reflected by the first sheet to convert the light reflected by the first sheet into electrical energy;
a second PV mechanism below the first PV mechanism and to receive light reflected by the second sheet to convert the light reflected by the second sheet into electrical energy,
such that the light assembly is a solar cell,
wherein the light is light from the sun.

9. The light assembly of claim 8, further comprising:
a frame to which the first and the second sheets are mounted; and,
a structure attached to a lower end of the frame, and to which the first and the second PV mechanisms are attached.

10. The light assembly of claim 9, wherein the first and the second sheets are mounted in relation to one another on the frame such that solar light is to first impinge the first sheet, and the solar light that is transmitted through the first sheet is then to impinge the second sheet.

11. A method comprising:
coating a first sheet so that the first sheet has a dichroic surface;
coating a second sheet so that the second sheet has a reflective surface; and,
after coating the first and the second sheets, manipulating the first and the second sheets so that the first and the second sheets have a parabolic shape.

12. The method of claim 11, further comprising, after manipulating the first and the second sheets, mounting the first and the second sheets to a frame such that the second sheet is mounted to the frame below the first sheet.

13. The method of claim 12, further comprising:
attaching a first photovoltaic (PV) mechanism and a second PV mechanism to a structure such that the second PV mechanism is attached to the structure below the first PV mechanism;
attaching the structure to a lower end of the frame,
wherein the first PV mechanism is to receive light reflected by the first sheet to convert the light reflected by the first sheet into electrical energy,
wherein the second PV mechanism is to receive light reflected by the second sheet to convert the light reflected by the second sheet into electrical energy,
wherein the light is light from the sun.

14. A method comprising:
reflecting a first portion of light by a first sheet, the first sheet being parabolic in shape;
transmitting a second portion of the light by the first sheet; and,
reflecting the second portion of the light by a second sheet, the second sheet being parabolic in shape.

15. The method of claim 14, wherein the light is light from the sun, wherein reflecting the first portion of the light by the first sheet comprises reflecting the first portion of the light towards a first photovoltaic mechanism, and wherein reflecting the second portion of the light by the second sheet comprises reflecting the second portion of the light towards a second photovoltaic mechanism.
